(19) United States
(12) Patent Application Publication
(10) Pub. No.: US 2021/0183836 A1
(43) Pub. Date: Jun. 17, 2021

(54) SEMICONDUCTOR ELEMENT PACKAGE AND LIGHT-EMITTING DEVICE COMPRISING SAME

(71) Applicant: LG INNOTEK CO., LTD., Seoul (KR)

(72) Inventor: Jung Hun OH, Seoul (KR)

(21) Appl. No.: 17/052,631

(22) PCT Filed: May 3, 2019
(86) PCT No.: PCT/KR2019/005324

§ 371 Date: Nov. 3, 2020

(30) Foreign Application Priority Data
May 4, 2018 (KR) 10-2018-0051540

(51) Int. Cl. H01L 25/16; H01L 33/62

(52) U.S. Cl. CPC H01L 25/167; H01L 33/382; H01L 33/62; H01L 25/165

(57) ABSTRACT

An embodiment discloses a semiconductor element package and a light-emitting device comprising same. The semiconductor element package comprises: a body comprising a cavity; a first electrode and a second electrode arranged on the bottom surface of the cavity; a semiconductor element arranged on the first electrode; a protective element arranged on the first electrode and spaced apart from the semiconductor element; a first wire electrically connecting the semiconductor element and the second electrode; and a second wire electrically connecting the protective element and the second electrode. The second electrode is arranged to be spaced apart from the first electrode in a first direction. The second electrode overlaps the semiconductor element in the first direction. The protective element is arranged to deviate from the semiconductor element in a second direction that is perpendicular to the first direction. The first electrode comprises a groove arranged between the semiconductor element and the protective element.

### TECHNICAL FIELD

An embodiment relates to a semiconductor element package and a light-emitting device including the same.

### BACKGROUND ART

An exposure machine is a device which transfers a desired pattern to a photosensitive film by placing a mask, on which a desired pattern is formed, on a sample coated with a photo-resist, that is, a material which reacts to light, and irradiating ultraviolet rays.

For example, in a semiconductor element, a printed circuit board (PCB), and a display panel which are embedded as major components of an electronic device, fine circuit patterns can be formed using photolithography technology in an exposure process.

As a light source of such an ultraviolet exposure device, a mercury ultraviolet lamp, a halogen lamp, or the like can may be used, but these lamps have low efficiency and are expensive.

Recently, a semiconductor element package has been adopted as a light source of an ultraviolet exposure device.

A semiconductor element including a compound such as GaN, AlGaN or the like has many advantages, such as having wide and easily adjustable band gap energy, and thus can be used in various ways such as a light emitting device, a light receiving device, and various other diodes.

However, since a semiconductor element package for a light-emitting device such as an exposure machine or a curing machine are densely arranged in plurality for light uniformity, a size of the package is relatively small. Accordingly, since an electrode area also decreases, a problem in which an area where Zener diodes are arranged is restricted occurs. Further, there is a problem in that electrical connection of the Zener diodes becomes unstable.

### DISCLOSURE

### Technical Problem

An embodiment is directed to providing a semiconductor element package in which a mounting area of a Zener diode and a wire bonding area are secured.

Problems to be solved by the present invention are not limited to the above-described problems, and purposes and effects understood from solutions and embodiments which will be described below are also included.

### Technical Solution

A semiconductor element package according to an embodiment includes: a body including a cavity; a first electrode and a second electrode arranged on a bottom surface of the cavity; a semiconductor element arranged on the first electrode; a protective element arranged on the first electrode to be spaced apart from the semiconductor element; a first wire configured to electrically connect the semiconductor element to the second electrode; and a second wire configured to electrically connect the protective element to the second electrode, wherein the second electrode is arranged to be spaced apart from the first electrode in a first direction, the second electrode overlaps the semiconductor element in the first direction, the protective element is arranged to deviate from the semiconductor element in a second direction perpendicular to the first direction, and the first electrode includes a groove arranged between the semiconductor element and the protective element.

The first electrode may include a first sub region overlapping the second electrode in the first direction and a second sub region overlapping the second electrode in the second direction.

The semiconductor element may be arranged in the first sub region, and the protective element may be arranged in the second sub region.

The protective element may overlap the second electrode in the second direction.

The semiconductor element package may include a first separation region arranged between the second electrode and the first sub region, and a second separation region arranged between the second electrode and the second sub region, and the groove may be connected to the first separation region and the second separation region.

The groove may include a first groove facing a first corner of the semiconductor element and a second groove facing a third corner of the semiconductor element, and the first corner and the third corner may face each other in a diagonal direction.

The semiconductor element may include a conductive substrate, a semiconductor structure arranged on the conductive substrate, and an electrode pad electrically connected to a second conductive semiconductor layer of the semiconductor structure, and the conductive substrate may be electrically connected to a first conductive semiconductor layer of the semiconductor structure.

The semiconductor element package may include an alloy layer arranged between the conductive substrate and the first electrode.

The first wire may include an end arranged at the second electrode, the second wire may include an end arranged at the second electrode, and the end of the second wire may be arranged farther from the semiconductor element than the end of the first wire.

An area of the semiconductor element may be 30% to 50% of an area of the first electrode.

The semiconductor element may generate light in an ultraviolet wavelength band.

The semiconductor element package may include a light transmission substrate arranged on the body, and the light transmission substrate may transmit light in an ultraviolet wavelength band.

### Advantageous Effects

According to an embodiment, a mounting area of a Zener diode and a wire bonding region can be secured in a semiconductor element package.

Various useful advantages and effects of the present invention are not limited to the above and may be relatively easily understood in a process of describing exemplary embodiments of the present invention.

### DESCRIPTION OF DRAWINGS

FIG. 1 is a perspective view of a semiconductor element package according to one embodiment of the present invention.

FIG. 2 is an exploded perspective view of the semiconductor element package according to one embodiment of the present invention.

FIG. 3 is a view illustrating structures of a first electrode and a second electrode.

FIG. 4 is a view illustrating a problem in which mounting of a Zener diode becomes difficult during eutectic bonding of a semiconductor element.

FIG. 5 is a first modified example of FIG. 3.

FIG. 6 is a second modified example of FIG. 3.

FIG. 7 is a cross-sectional view of a semiconductor element according to one embodiment of the present invention.

FIG. 8 is a view illustrating a coupling relationship between a body and a substrate.

FIG. 9 is a cross-sectional view taken along line A-A in FIG. 1.

FIG. 10 is a perspective view taken along line B-B in FIG. 2.

FIG. 11 is a conceptual diagram of a light-emitting device according to one embodiment of the present invention.

### MODES OF THE INVENTION

The embodiments may be modified into other forms or some of the embodiments may be combined, and the scope of the present invention is not limited to embodiments which will be described below.

Although items described in a specific embodiment are not described in another embodiment, the items may be understood as a description related to the other embodiment unless a description contrary to or contradicting the items is in the other embodiment.

For example, when a feature of a component A is described in a specific embodiment and a feature of a component B is described in another embodiment, even when an embodiment in which the component A and the component B are combined is not clearly described, it should be understood as falling within the scope of the present invention unless a contrary or contradictory description is present.

In the description of the embodiments, when one element is described as being formed “on or under” another element, the term “on or under” includes both a case in which the two elements are in direct contact with each other and a case in which at least one other element is arranged between the two elements (indirect contact). Further, when the term “on or under” is expressed, a meaning of not only an upward direction but also a downward direction with respect to one element may be included.

Hereinafter, embodiments of the present invention will be described in detail with reference to the accompanying drawings so that those skilled in the art may easily carry out the embodiment of the present invention.

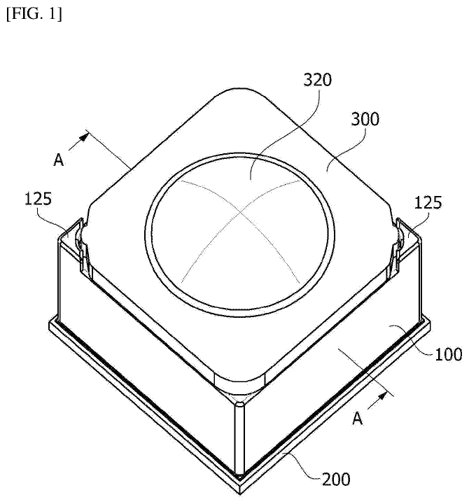

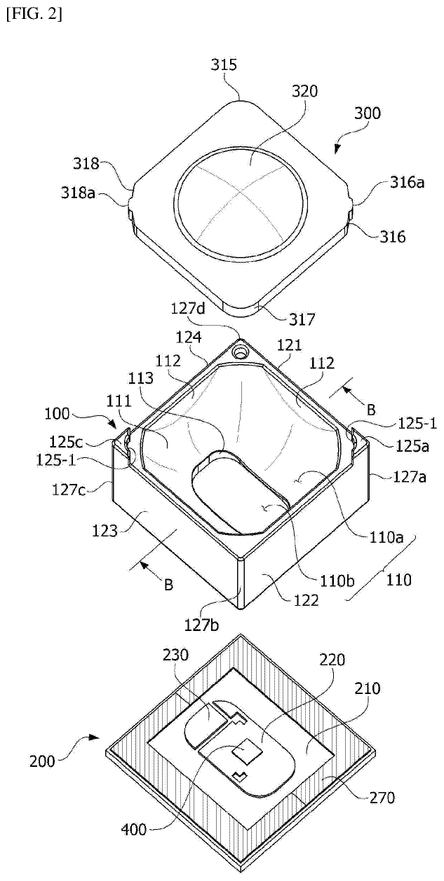

FIG. 1 is a perspective view of a semiconductor element package according to one embodiment of the present invention, and FIG. 2 is an exploded perspective view of the semiconductor element package according to one embodiment of the present invention.

Referring to FIGS. 1 and 2, the semiconductor element package according to the embodiment may include bodies 100 and 200, a semiconductor element 400 arranged in the bodies 100 and 200, and a light transmission member 300 arranged on the bodies 100 and 200.

The bodies 100 and 200 may include a substrate 200 and a sidewall portion 100 arranged on the substrate 200 and including a cavity 110.

The substrate 200 may include an AlN material. However, the present invention is not limited thereto, and various materials capable of reflecting ultraviolet light may be selected. For example, the substrate 200 may include aluminum oxide (Al2O3). The substrate 200 may have a polygonal shape. For example, the substrate 200 may have a quadrangular shape.

A first electrode 220 and a second electrode 230 may be arranged on one surface of the substrate 200. The first electrode 220 and the second electrode 230 may include at least one among Ti, Ru, Rh, Jr, Mg, W, Zn, Al, In, Ta, Pd, Co, Ni, Si, Ge, Ag, and Au. For example, each of the first electrode 220 and the second electrode 230 may have a sequentially stacked structure of W/Ti/Ni/Cu/Pd/Au.

An area of the second electrode 230 may be smaller than an area of the first electrode 220. This is because the semiconductor element 400 and a Zener diode 500 are arranged on the first electrode 220 whereas the second electrode 230 requires only a region to which a wire is bonded. For example, the area of the second electrode 230 may be 20% to 40% of an area of the first electrode 220. When the area of the second electrode 230 is smaller than 20%, there is a problem in that a wire bonding region is not sufficiently secured and thus electrical reliability is lowered, and when the area of the second electrode 230 is greater than 40%, there is a problem in that the area of the first electrode 220 decreases and thus a separation distance between the semiconductor element 400 and the Zener diode 500 becomes narrow.

The semiconductor element 400 may be arranged on the first electrode 220, and may be electrically connected to the second electrode 230 through the wire. However, the present invention is not limited thereto, and the semiconductor element 400 may be electrically connected to the second electrode 230 and the first electrode 220 through the wire. In addition, the semiconductor element 400 may be implemented as a flip chip and thus may be arranged on the second electrode 230 and the first electrode 220. That is, the semiconductor element 400 may be electrically connected to the second electrode 230 and the first electrode 220 in various ways according to an electrode structure.

The semiconductor element 400 may output light in an ultraviolet wavelength band. For example, the semiconductor element 400 may output light having a peak in a near ultraviolet wavelength band (ultraviolet (UV)-A), may output light having a peak in a middle ultraviolet wavelength band (UV-B), and may output light having a peak in a deep ultraviolet wavelength band (UV-C). The wavelength range may be determined by a composition ratio of Al in a semiconductor structure. However, the present invention is not limited thereto, and the semiconductor element 400 may be manufactured to output light in a wavelength band required for exposure.

The sidewall portion 100 may including a first outer side surface 121 and a third outer side surface 123 facing each other, a second outer side surface 122 and a fourth outer side surface 124 facing each other, a first corner portion 127a arranged between the first outer side surface 121 and the second outer side surface 122, a second corner portion 127b arranged between the second outer side surface 122 and the third outer side surface 123, a third corner portion 127c arranged between the third outer side surface 123 and the fourth outer side surface 124, and a fourth corner portion 127d arranged between the fourth outer side surface 124 and the first outer side surface 121. The sidewall portion 100 may have a polygonal shape, for example, a quadrangular shape.

The sidewall portion 100 may include the cavity 110 which passes through an upper surface and a lower surface thereof. An inner side surface of the cavity 110 may reflect ultraviolet light. For example, the sidewall portion 100 itself may reflect the ultraviolet light like AlN/aluminum oxide, or a separate reflective layer may be arranged in the cavity 110.

The cavity 110 may include a first cavity 110a having an inclined first surface 111 and a second surface 112 perpendicular to the substrate 200, and a second cavity 110b which exposes the semiconductor element 400. The second cavity 110b may have a quadrangular shape, but is not limited thereto. For example, the second cavity 110b may have a shape corresponding to a shape of each of the first electrode 220 and the second electrode 230.

The sidewall portion 100 may include a plurality of protrusions 125a and 125c protruding from corner portions facing in a diagonal direction among the first to fourth corner portions 127a, 127b, 127c, and 127d.

For example, the plurality of protrusions 125a and 125c may include a first protrusion 125a protruding from the first corner portion 127a, and a third protrusion 125c protruding from the third corner portion 127c. In this case, each of the second corner portion 127b and the fourth corner portion 127d not formed with the protrusion may provide a space where a vacuum chuck holds the sidewall portion 100.

However, the present invention is not limited thereto, and the sidewall portion 100 may further include a second protrusion (not shown) protruding from the second corner portion 127b and a fourth protrusion (not shown) protruding from the fourth corner portion 127d.

Each of the first and third protrusions 125a and 125c may have a polygonal pillar shape. For example, each of the first and third protrusions 125a and 125c may include a triangular pillar shape, but is not limited thereto, and may have a quadrangular pillar shape or a pentagonal pillar shape.

The light transmission member 300 may be arranged on the sidewall portion 100 to control light emitted from the semiconductor element 400. The light transmission member 300 may include a lens part 320. The lens part 320 may control luminous flux so that the light emitted from the semiconductor element 400 may be uniformly emitted. An example in which the lens part 320 has a dome shape is described, but the present invention is not limited thereto, and the lens part 320 may have various curvatures to be capable of uniformly controlling the light.

The light transmission member 300 may include a first corner portion 316 and a third corner portion 318 facing each other, and a second corner portion 317 and a fourth corner portion 315 facing each other. The light transmission member 300 may have a polygonal shape, for example, a quadrangular shape.

The light transmission member 300 may include a flat surface arranged at corner portions facing the plurality of protrusions 125a and 125c. Accordingly, the light transmission member 300 may be fixed by the first and third protrusions 125a and 125c.

In this case, the first protrusion 125a and the third protrusion 125c may include a first fastening portions 125-1 arranged on surfaces facing each other, and the light transmission member 300 may include second fastening portions 316a and 318a arranged at the first corner portion 316 and the third corner portion 318 and coupled to the first fastening portions 125-1.

In this case, the first fastening portions 125-1 may be protrusions and the second fastening portions 316a and 318a may be grooves but are not limited thereto. For example, the first fastening portions 125-1 may be grooves and the second fastening portions 316a and 318a may be protrusions. The first fastening portions 125-1 and the second fastening portions 316a and 318a may extend in a protruding direction of the first and third protrusions 125a and 125c. According to this configuration, the light transmission member 300 may be stably inserted into and fixed to the first and third protrusions 125a and 125c.

The light transmission member 300 may be fixed to one surface of the sidewall portion 100 by an adhesive (not shown). The adhesive may be a UV curable resin, but is not limited thereto.

The light transmission member 300 is not particularly limited as long as it is a material capable of transmitting light in the ultraviolet wavelength band. For example, the light transmission member 300 may include an optical material having high UV wavelength transmittance such as quartz or glass, but is not limited thereto.

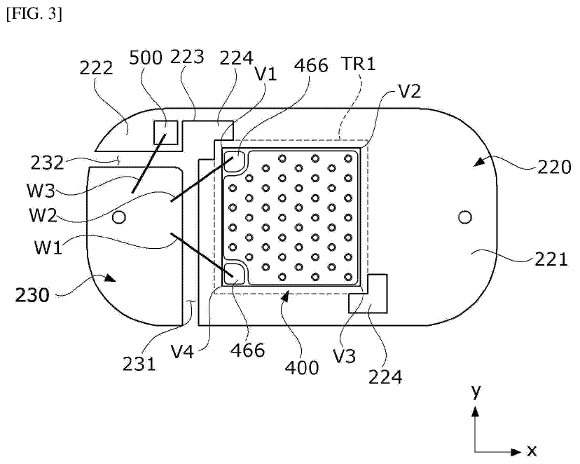

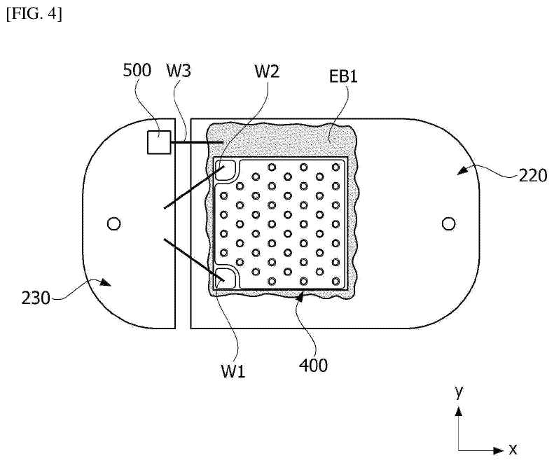

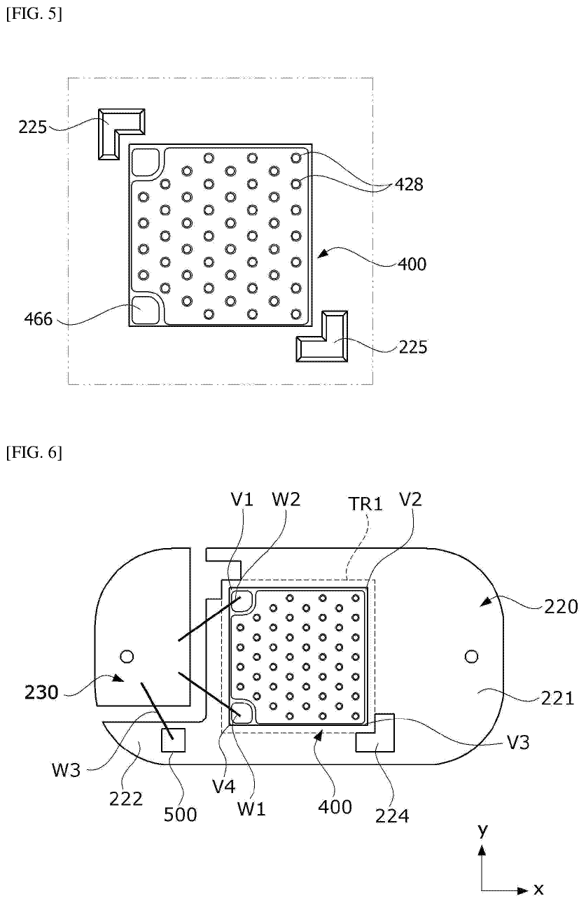

FIG. 3 is a view illustrating structures of a first electrode and a second electrode, FIG. 4 is a view illustrating a problem in which mounting of a Zener diode becomes difficult during eutectic bonding of the semiconductor element, FIG. 5 is a first modified example of FIG. 3, and FIG. 6 is a second modified example of FIG. 3.

Referring to FIG. 3, the first electrode 220 may include a first sub region 221 where the semiconductor element 400 is arranged and a second sub region 222 where a protective element such as the Zener diode 500 is arranged. Further, the first electrode 220 may include an extending portion 223 which connects the first sub region 221 and the second sub region 222.

The first sub region 221 may include a plurality of grooves 224 arranged in a diagonal direction. The plurality of grooves 224 may be alignment grooves enabling recognition of a region where the semiconductor element 400 is arranged. A bottom surface of the cavity 110 or an upper surface of the substrate 200 may be exposed by the plurality of grooves 224. That is, the plurality of grooves 224 may be holes which expose the bottom surface of the cavity 110 or the upper surface of the substrate 200.

The plurality of grooves 224 may include a first groove 224 facing a first corner V1 of the semiconductor element 400 and a second groove 224 facing a third corner V3 of the semiconductor element 400. However, the present invention is not limited thereto, and the plurality of grooves 224 may additionally include grooves facing a second corner V2 and a fourth corner V4 of the semiconductor element 400.

The semiconductor element 400 may be arranged in the largest quadrangular region TR1 surrounded by the first groove 224 and the second groove 224. For example, when the semiconductor element 400 is a vertical type, P-type electrode pads 466 may be electrically connected to the second electrode 230 by first wires W1 and W2. In this case, although an example in which the number of P-type electrode pads 466 is two is illustrated, it is not necessarily limited thereto. For example, the number of P-type electrode pads 466 may be one.

The semiconductor element 400 may be electrically connected to the first electrode 220 by a metal layer. Specifically, an alloy layer may be arranged between a conductive substrate of the semiconductor element 400 and the first electrode 220. The alloy layer may include at least one of Au, In, Cu, Sn, and Ni. For example, the alloy layer may include a eutectic metal such as Au—In, Cu—Sn, In—Sn, Au—Cu, Au—Sn, and Ni—Sn. Eutectic bonding has the advantage of excellent heat dissipation.

However, an electrical connection method is not necessarily limited thereto, and various methods of electrically connecting the semiconductor element such as solder paste may be included. Hereinafter, the eutectic bonding will be described as an example.

In the eutectic bonding, after a eutectic metal is applied to the quadrangular region TR1, the semiconductor element 400 may be arranged thereon. However, there is a problem in that the eutectic metal has good fluidity and thus flows to an outer side of the quadrangular region TR1.

As shown in FIG. 4, the eutectic metal EB1 may flow to cover the wire bonding region of the Zener diode 500. In this case, there may be a problem in that a wire W3 is not properly bonded by the eutectic metal.

Generally, since a semiconductor element package for exposure is densely arranged in plurality and uniform light should be irradiated to a target, it may be important to reduce a size of the package. Accordingly, an electrode area in the package may also be reduced.

Since the electrode area of the semiconductor element package for exposure is small, there is a problem in which it is difficult to secure an area for mounting the Zener diode 500 when the eutectic metal flows to an outer side of the semiconductor element 400.

Referring back to FIG. 3, in the embodiment, a protective element 500 such as the Zener diode may be arranged in the second sub region 222 of the first electrode 220, and the Zener diode 500 may be electrically connected to the second electrode 230 by a second wire W3.

The Zener diode 500 is arranged to overlap the second metal 230 in a second direction (a Y-axis direction), and thus may be arranged to deviate from the semiconductor element 400 in the second direction (the Y-axis direction). Accordingly, even when the eutectic metal flows to the outer side of the semiconductor element 400, the mounting area of the Zener diode 500 may be secured. Further, an end of the second wire W3 connected to the second electrode 230 may be arranged farther from the semiconductor element in a first direction (an X-axis direction) than the ends of first wires W1 and W2. That is, the shortest distance between the end of the second wire W3 and the semiconductor element 400 may be greater than the shortest distances between the ends of the first wires W1 and W2 and the semiconductor element 400.

The first groove 224 may be arranged between the Zener diode 500 and the semiconductor element 400 to prevent the eutectic metal from flowing to the second sub region 222. Accordingly, the first groove 224 may block the eutectic metal from flowing to the area where the Zener diode 500 is arranged. Specifically, the first groove 224 may be arranged between the first corner V1 of the semiconductor element 400 and the Zener diode 500.

The first groove 224 may serve as a dam which indicates a mounting region of the semiconductor element 400 and prevents the eutectic metal from flowing to a mounting region of the Zener diode 500.

The groove 224 may have a bracket shape such as “┐”, but is not limited thereto. For example, the groove 224 may have a rod shape or an arc shape. Alternatively, the groove 224 may be arranged in the first electrode 220 in the form of an opening to expose the upper surface of the substrate.

The shape of the groove 224 is not particularly limited as long as it may serve to indicate a mounting position of the semiconductor element 400 and prevent the eutectic metal from flowing to the mounting region of the Zener diode 500. For example, as shown in FIG. 5, the groove 224 may be modified into a protrusion shape 225. Further, the shape of the protrusion 225 may be variously modified.

Referring to FIG. 3, the first sub region 221 may be a region overlapping the second electrode 230 in the first direction (the X-axis direction). Further, the second sub region 222 may be a region overlapping the second electrode 230 in the second direction (the Y-axis direction). That is, the second sub region 222 may protrude from the first sub region 221 in the first direction (the X-axis direction).

A first separation region 231 may be formed between the second electrode 230 and the first sub region 221, and a second separation region 232 may be formed between the second electrode 230 and the second sub region 222. That is, the second electrode 230 may be spaced apart from the first electrode 220 in the first direction (the X-axis direction) and the second direction (the Y-axis direction). In this case, the first groove 224 may be connected at a point where the first separation region 231 and the second separation region 232 meet. That is, the first groove 224 may be diagonally arranged toward the second electrode 230 and thus may be arranged between the semiconductor element 400 and the Zener diode 500.

An area of the semiconductor element 400 may be 30% to 50% of an area of the first electrode 220. When the area of the semiconductor element 400 is smaller than 30%, there is a problem in that the size of the semiconductor element 400 decreases and the output of the ultraviolet light is weakened, and when the area of the semiconductor element 400 is greater than 50%, there is a problem of difficulty in securing a space on which the Zener diode 500 is mounted.

Referring to FIG. 6, the second sub region 222 may be arranged not at a position where the first groove 224 is arranged, but at a position adjacent to the fourth corner V4 of the semiconductor element 400. However, even in this case, the Zener diode 500 may be arranged not to overlap the semiconductor element 400 in the second direction (the Y-axis direction). Accordingly, it may be designed so that the eutectic metal arranged under the semiconductor element 400 does not flow to a mounting position of the Zener diode 500.

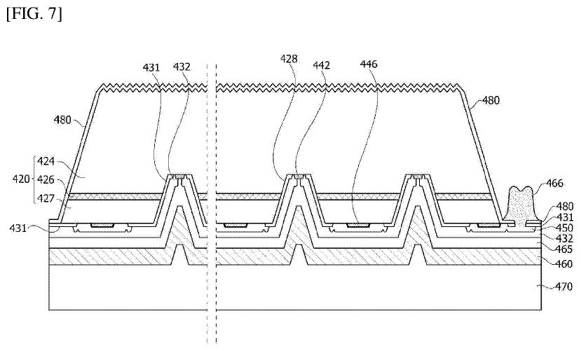

FIG. 7 is a cross-sectional view of the semiconductor element according to one embodiment of the present invention.

As described above, although all of horizontal type, vertical type, and flip chip structures may be applied to the semiconductor element according to the embodiment, by way of example, the semiconductor element may have a vertical structure.

The semiconductor element includes a light emitting structure 420, first electrodes 442 and 465 electrically connected to a first conductive semiconductor layer 424 of the light emitting structure 420, and second electrodes 446 and 450 electrically connected to a second conductive semiconductor layer 427.

The light emitting structure 420 may include the first conductive semiconductor layer 424, the second conductive semiconductor layer 427, and an active layer 426 arranged between the first conductive semiconductor layer 424 and the second conductive semiconductor layer 427.

The first conductive semiconductor layer 424 may be implemented with a group III-V or II-VI compound semiconductor, and may be doped with a first dopant. The first conductive semiconductor layer 424 may be selected from a semiconductor material having a composition formula of Inx1Aly1Ga1-x1-y1N (x1 is 0 to 1, y1 is 0 to 1, and x1+y1 is 0 to 1), for example, GaN, AlGaN, InGaN, InAlGaN, and the like. Further, the first dopant may be an n-type dopant such as Si, Ge, Sn, Se, and Te. When the first dopant is an n-type dopant, the first conductive semiconductor layer 424 doped with the first dopant may be an n-type semiconductor layer.

The active layer 426 is arranged between the first conductive semiconductor layer 424 and the second conductive semiconductor layer 427. The active layer 426 is a layer in which electrons (or holes) injected through the first conductive semiconductor layer 424 and holes (or electrons) injected through the second conductive semiconductor layer 427 meet. The active layer 426 transitions to a lower energy level due to recombination of the electrons and the holes, and may generate light having an ultraviolet wavelength.

The active layer 426 may have one structure among a single well structure, a multiple well structure, a single quantum well structure, a multi quantum well (MQW) structure, a quantum dot structure, and a quantum wire structure, but the structure of the active layer 426 is not limited thereto.

The second conductive semiconductor layer 427 may be formed on the active layer 426, may be implemented with a group III-V or II-VI compound semiconductor, and may be doped with a second dopant. The second conductive semiconductor layer 427 may be formed of a semiconductor material having a composition formula of Inx5Aly2Ga1-x5-y2N (x5 is 0 to 1, y2 is 0 to 1, and x5+y2 is 0 to 1), or a material selected from AlInN, AlGaAs, GaP, GaAs, GaAsP, and AlGaInP. When the second dopant is a p-type dopant such as Mg, Zn, Ca, Sr, Ba, or the like, the second conductive semiconductor layer 427 doped with the second dopant may be a p-type semiconductor layer.

The light emitting structure according to the embodiment may include a plurality of recesses 428.

The plurality of recesses 428 may be arranged up to a partial region of the first conductive semiconductor layer 424 through the active layer 426 from a lower surface 427G of the second conductive semiconductor layer 427. A first insulating layer 431 may be arranged in the recesses 428 to insulate a first conductive layer 465 from the second conductive semiconductor layer 427 and the active layer 426.

The first electrodes 442 and 465 may include a first contact electrode 442 and the first conductive layer 465. The first contact electrode 442 may be arranged on an upper surface of the recess 428 to be electrically connected to the first conductive semiconductor layer 424.

When aluminum composition of the light emitting structure 420 increases, current spreading characteristics in the light emitting structure 420 may deteriorate. Further, in the active layer, an amount of light emitted to the side surface increases in comparison with a GaN-based blue light emitting device (a transverse magnetic (TM) mode). This TM mode may mainly occur in an ultraviolet semiconductor element.

The ultraviolet semiconductor element has an inferior current spreading characteristic in comparison with a blue GaN semiconductor element. Accordingly, a relatively larger number of first contact electrodes 442 have to be arranged in the ultraviolet semiconductor element in comparison with the blue GaN semiconductor element.

A second electrode pad 466 may be arranged in one side corner region of the semiconductor element.

Since the first insulating layer 431 is partially open under the electrode pad 466, a second conductive layer 450 and a second contact electrode 446 may be electrically connected.

A passivation layer 480 may be formed on an upper surface and side surfaces of the light emitting structure 420. The passivation layer 480 may come into contact with the first insulating layer 431 in a region adjacent to the second contact electrode 446 or under the second contact electrode 446.

The first insulating layer 431 may electrically insulate the first contact electrode 442 from the active layer 426 and the second conductive semiconductor layer 427. Further, the first insulating layer 431 may electrically insulate the second conductive layer 450 from the first conductive layer 465.

The first insulating layer 431 may be formed by selecting at least one from the group consisting of SiO2, SixOy, Si3N4, SixNy, SiOxNy, Al2O3, TiO2, AN, and the like, but is not limited thereto. The first insulating layer 431 may be formed as a single layer or multiple layers. For example, the first insulating layer 431 may be a distributed Bragg reflector (DBR) having a multilayer structure including Si oxide or a Ti compound. However, the present invention is not necessarily limited thereto, and the first insulating layer 431 may include various reflective structures.

When the first insulating layer 431 performs a reflective function, light emitted in the active layer 426 toward the side surface may be reflected upward to enhance light extraction efficiency. In the ultraviolet semiconductor element, as the number of recesses 428 increases, light extraction efficiency may be more effective, in comparison with a semiconductor element emitting blue light.

The second electrodes 446 and 450 may include the second contact electrode 446 and the second conductive layer 450.

The second contact electrode 446 may come into contact with a lower surface of the second conductive semiconductor layer 427. The second contact electrode 446 may include a conductive oxide electrode with relatively low absorption of ultraviolet light. For example, the conductive oxide electrode may be indium tin oxide (ITO), but is not limited thereto.

The second conductive layer 450 may inject a current into the second conductive semiconductor layer 427. Further, the second conductive layer 450 may reflect the light emitted from the active layer 426.

The second conductive layer 450 may cover the second contact electrode 446. Accordingly, the second electrode pad 466, the second conductive layer 450, and the second contact electrode 446 may form one electrical channel.

The second conductive layer 450 may come into contact with side surfaces and a lower surface of the first insulating layer 431 while surrounding the second contact electrode 446. The second conductive layer 450 may be formed of a material having good adhesion with the first insulating layer 431, may be formed of at least one material selected from the group consisting of materials such as Cr, Al, Ti, Ni, Au, and the like, or an alloy thereof, and may be formed as a single layer or a plurality of layers.

When the second conductive layer 450 comes into contact with the side surfaces and the lower surface of the first insulating layer 431, thermal and electrical reliability of the second contact electrode 446 may be enhanced. Further, the second conductive layer 450 may have a reflective function of reflecting light emitted between the first insulating layer 431 and the second contact electrode 446 upward.

A second insulating layer 432 may electrically insulate the second conductive layer 450 from the first conductive layer 465. The first conductive layer 465 may be electrically connected to the first contact electrode 442 through the second insulating layer 432.

The first conductive layer 465 and a bonding layer 460 may be arranged along a lower surface of the light emitting structure 420 and a shape of the recess 428. The first conductive layer 465 may be made of a material having excellent reflectivity. For example, the first conductive layer 465 may include aluminum. When the first conductive layer 465 includes aluminum, the first conductive layer 465 may serve to upwardly reflect the light emitted from the active layer 426 to enhance the light extraction efficiency.

The bonding layer 460 may include a conductive material. For example, the bonding layer 460 may include a material selected from the group consisting of gold, tin, indium, aluminum, silicon, silver, nickel, and copper, or an alloy thereof.

A conductive substrate 470 may be formed of a conductive material to inject a current into the first conductive semiconductor layer 424. For example, the conductive substrate 470 may include a metal or semiconductor material. The conductive substrate 470 may be a metal having excellent electrical conductivity and/or thermal conductivity. In this case, heat generated during the operation of the semiconductor element may be quickly dissipated to the outside.

The conductive substrate 470 may include a material selected from the group consisting of silicon, molybdenum, silicon, tungsten, copper, and aluminum, or an alloy thereof.

An unevenness may be formed on an upper surface of the light emitting structure 420. This unevenness may enhance extraction efficiency of light emitted from the light emitting structure 420. The unevenness may have different average heights depending on the UV wavelength, and in the case of UV-C, light extraction efficiency may be enhanced when the height is approximately 300 nm to 800 nm and the average height is approximately 500 nm to 600 nm.

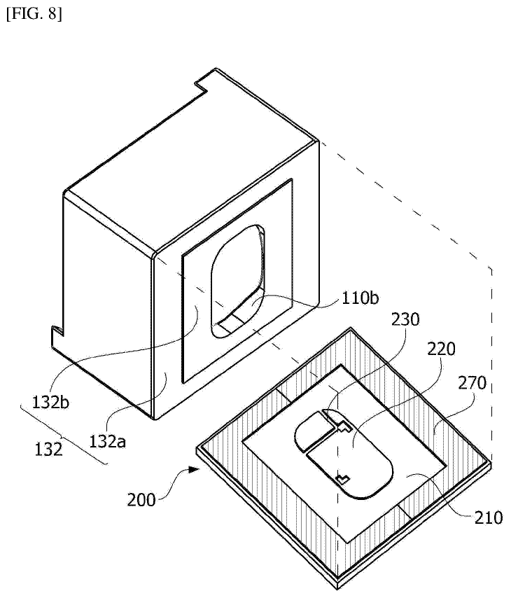

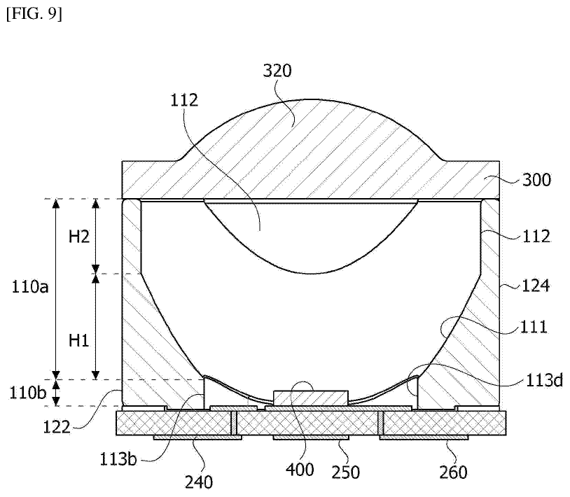

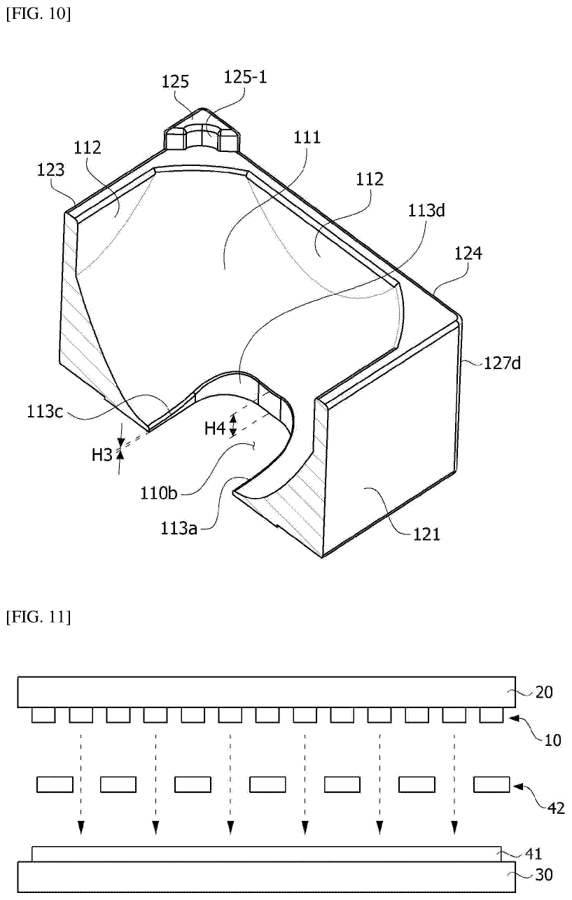

FIG. 8 is a view illustrating a coupling relationship between a body and a substrate, FIG. 9 is a cross-sectional view taken along line A-A in FIG. 1, and FIG. 10 is a perspective view taken along line B-B in FIG. 2.

Referring to FIG. 8, the substrate 200 may include the second electrode 230 where the semiconductor element 400 is arranged, the first electrode 220 arranged to be spaced apart from the second electrode 230, and a first protruding portion 270 arranged along an edge of the substrate 200.

The first electrode 220, the second electrode 230, and the first protruding portion 270 may be manufactured by forming an electrode layer on the substrate 200 and then patterning the electrode layer. That is, the first protruding portion 270 may be electrically insulated from the semiconductor element 400. Accordingly, the first electrode 220, the second electrode 230, and the first protruding portion 270 may have the same material. For example, the first electrode 220, the second electrode 230, and the first protruding portion 270 may be selected from Ti, Ru, Rh, Jr, Mg, Zn, Al, In, Ta, Pd, Co, Ni, Si, Ge, Ag, and Au, and an optional alloy thereof.

A thickness of the first protruding portion 270 may be the same as thicknesses of the first electrode 220 and the second electrode 230. However, the present invention is not necessarily limited thereto, and the thickness of the first protruding portion 270 may be greater than the thicknesses of the first electrode 220 and the second electrode 230.

A second protruding portion 132b in which the second cavity 110b is arranged and a concave portion 132a arranged along an edge may be arranged in a lower surface 132 of the sidewall portion 100, and the first protruding portion 270 may be inserted into the concave portion 132a. Accordingly, assembly of the substrate 200 and the sidewall portion 100 may be facilitated and alignment may be improved. Further, it is possible to prevent the sidewall portion 100 from rotating after assembly.

Referring to FIGS. 9 and 10, the cavity 110 according to the embodiment may include the first cavity 110a having the inclined first surface 111 and the second surface 112 perpendicular to the substrate 200, and the second cavity 110b which exposes the semiconductor element 400.

The first surface 111 may have a parabolic shape in which a cross-sectional area increases as a distance from the substrate 200 increases. Accordingly, since the light emitted from the semiconductor element 400 is reflected upward, the luminous flux may increase and uniform light distribution may be provided.

The second surface 112 may be arranged on the first surface 111 and may be arranged perpendicular to the substrate 200. The second surface 112 may reduce a size of the semiconductor element package. When the first cavity 110a has a parabolic shape as a whole by the first surface 111, the size of the semiconductor element package should be increased.

According to the embodiment, the second surface 112 may be partially formed in the first cavity 110a to reduce the size of the semiconductor element package. Accordingly, the semiconductor element package may be densely arranged.

A ratio (H1:H2) of vertical maximum widths of the first surface 111 and the second surface 112 may be 1:0.5 to 1:0.7. When the ratio is greater than 1:0.5, the second surface 112 becomes wide to reduce the size of the semiconductor element package, and when the ratio is smaller than 1:0.7, the second surface 112 is too wide and thus a problem in that the luminous flux is reduced due to total reflection may be prevented.

Referring to FIGS. 2 and 9, the second surface 112 may be arranged between the corner portions of the sidewall portion 100. For example, a plurality of second surfaces 112 may be arranged between the first corner portion 127a and the second corner portion 127b, between the second corner portion 127b and the third corner portion 127c, between the third corner portion 127c and the fourth corner portion 127d, and between the fourth corner portion 127d and the first corner portion 127a, respectively.

In this case, the vertical widths of the second surfaces 112 may decrease while approaching the first to fourth corner portions 127a, 127b, 127c, and 127d. Accordingly, the second surface 112 may have a semicircular shape. When a vertical width H2 of the second surface 112 increases or stays the same while approaching the first to fourth corner portions 127a, 127b, 127c, and 127d, it is difficult for the first cavity 110a to have a parabolic shape as a whole, and thus it is difficult to have the desired light distribution. Further, the luminous flux may be reduced.

The first surface 111 may extend to a region between the plurality of second surfaces 112. That is, the first surface 111 may extend to the first to fourth corner portions 127a, 127b, 127c, and 127d to partition the plurality of second surfaces 112.

The second cavity 110b may be arranged under the first cavity 110a. The second cavity 110b may be arranged to surround the semiconductor element 400. The second cavity 110b may have a polygonal shape or a circular shape.

Referring to FIGS. 9 and 10, the second cavity 110b may include a third surface 113 perpendicular to the substrate 200. The third surface 113 of the second cavity 110b may be parallel to the second surface 112.

The third surface 113 of the second cavity 110b may include a first inner side surface 113a and a third inner side surface 113c facing each other, and a second inner side surface 113b and a fourth inner side surface 113d facing each other, horizontal lengths of the first inner side surface 113a and the third inner side surface 113c may be greater than those of the second inner side surface 113b and the fourth inner side surface 113d, and vertical widths H4 of the second inner side surface 113b and the fourth inner side surface 113d may be greater than vertical widths H3 of the first inner side surface 113a and the third inner side surface 113c.

The first inner side surface 113a of the second cavity 110b may be arranged to face the first outer side surface 121 of the sidewall portion 100, and the third inner side surface 113c may be arranged to face the third outer side surface 123 of the sidewall portion 100.

Further, the second inner side surface 113b of the second cavity 110b may be arranged to face the second outer side surface 122 of the sidewall portion 100, and the fourth inner side surface 113d may be arranged to face the fourth outer side surface 124 of the sidewall portion 100.

The vertical widths H3 of the first inner side surface 113a and the third inner side surface 113c of the second cavity 110b may increase while approaching the second inner side surface 113b and the fourth inner side surface 113d of the second cavity 110b. According to this configuration, since a shape of the second cavity 110b arranged under the first surface 111 may be formed in a polygonal shape, a wire mounting area and the like may be secured. Accordingly, reliability of the element may be improved. The vertical widths H4 of the second inner side surface 113b and the fourth inner side surface 113d may be smaller than the vertical width H2 of the first surface 111.

FIG. 11 is a conceptual diagram of a light-emitting device according to one embodiment of the present invention.

The light-emitting device according to the embodiment may include a stage 30 and light source modules 10 and 20 arranged on the stage 30. The light-emitting device according to the embodiment may be a concept including a sterilization device, a curing device, an exposure device, a lighting device, a display device, a vehicle lamp, and the like. Hereinafter, for example, the light-emitting device will be described as an exposure machine.

An exposure target 41 may be arranged on the stage 30, and a mask pattern 42 may be arranged between the exposure target 41 and the light source modules 10 and 20. Accordingly, the ultraviolet light may be selectively incident on the exposure target 41 according to the mask pattern 42. All of the structures of a conventional exposure machine may be applied to this structure.

The light source modules 10 and 20 may include a circuit board 20 and a plurality of semiconductor element packages 10 arranged on the circuit board 20. It may be important to arrange the plurality of semiconductor element packages 10 are arranged as densely as possible in the light source modules 10 and 20 of the light-emitting device. Luminous flux and illuminance uniformity on the target surface may be improved as an interval of the semiconductor element packages becomes narrower. A structure of the semiconductor element package 10 may include all of the above-mentioned features.

The semiconductor element may be applied to various types of light emitting devices. For example, the light emitting device may be a concept including a sterilization device, a curing device, an exposure device, a lighting device, a display device, a vehicle lamp, and the like. That is, the semiconductor element may be applied to various electronic devices which are arranged in a case and provide light.

The sterilization device may sterilize a desired area by including the semiconductor element according to the embodiment. The sterilization device may be applied to household appliances such as a water purifier, an air conditioner, a refrigerator, and the like, but is not limited thereto. That is, the sterilization device may be applied to all products (for example, a medical device) which require sterilization.

For example, the water purifier may be provided with the sterilization device according to the embodiment to sterilize circulating water. The sterilization device is arranged in a nozzle or an outlet through which the water circulates to irradiate ultraviolet rays. In this case, the sterilization device may include a waterproof structure.

The curing device may cure various types of liquid by including the semiconductor element according to the embodiment. The liquid may be the broadest concept including all various materials which are cured when irradiated with ultraviolet rays. For example, the curing device may cure various types of resins. Alternatively, the curing device may be applied to cure cosmetic products such as a manicure.

The exposure device may transfer a desired pattern onto a photosensitive film by placing a mask, on which a desired pattern is formed, on a sample coated with a photo-resist as a material which reacts to light, and irradiating ultraviolet rays. For example, in a semiconductor element, a printed circuit board (PCB), and a display panel which are embedded as major components of an electronic device, fine circuit patterns may be formed using photolithography technology in an exposure process.

The lighting device may include a light source module including a substrate and the semiconductor element of the embodiment, a heat dissipation part which dissipates heat from the light source module, and a power supply part which processes or converts an electrical signal provided from the outside to provide the electrical signal to the light source module. Further, the lighting device may include a lamp, a head lamp, a street light, or the like.

Although the above-described embodiments are mainly described with reference to the embodiments of the present invention, the above are only exemplary, and it should be understood that those skilled in the art may variously perform modifications and applications within the principle of the embodiments. For example, elements specifically shown in the embodiments may be modified. Further, differences related to modifications and changes should be understood as being included in the scope of the present invention defined in the appended claims.

1. A semiconductor element package comprising:
a body including a cavity;
a first electrode and a second electrode arranged on a bottom surface of the cavity;
a semiconductor element arranged on the first electrode;
a protective element arranged on the first electrode to be spaced apart from the semiconductor element;
a first wire configured to electrically connect the semiconductor element to the second electrode; and
a second wire configured to electrically connect the protective element to the second electrode,
wherein the second electrode is arranged to be spaced apart from the first electrode in a first direction,
the second electrode overlaps the semiconductor element in the first direction,
the protective element is arranged to deviate from the semiconductor element in a second direction perpendicular to the first direction, and
the first electrode includes a groove arranged between the semiconductor element and the protective element.

2. The semiconductor element package of claim 1, wherein:
the first electrode includes a first sub region overlapping the second electrode in the first direction and a second sub region overlapping the second electrode in the second direction;
the semiconductor element is arranged in the first sub region; and
the protective element is arranged in the second sub region.

3. The semiconductor element package of claim 2, wherein:
the protective element overlaps the second electrode in the second direction; and
the protective element is arranged to deviate from the semiconductor element in the first direction.

4. The semiconductor element package of claim 2, comprising a first separation region arranged between the second electrode and the first sub region, and a second separation region arranged between the second electrode and the second sub region,
wherein the groove is connected to the first separation region and the second separation region.

5. The semiconductor element package of claim 1, comprising a second groove facing a third corner of the semiconductor element,
wherein the groove is arranged to face a first corner of the semiconductor element, and
the first corner and the third corner face each other in a diagonal direction.

6. The semiconductor element package of claim 1, wherein:
the semiconductor element includes a conductive substrate, an alloy layer arranged between the conductive substrate and the first electrode, a semiconductor structure arranged on the conductive substrate, and an electrode pad electrically connected to a second conductive semiconductor layer of the semiconductor structure; and
the conductive substrate is electrically connected to a first conductive semiconductor layer of the semiconductor structure.

7. The semiconductor element package of claim 1, wherein:
the first wire includes an end arranged at the second electrode;
the second wire includes an end arranged at the second electrode; and
the shortest distance between the end of the second wire and the semiconductor element is longer than the shortest distance between the end of the first wire and the semiconductor element.

8-10. (canceled)

11. The semiconductor element package of claim 1, wherein an area of the semiconductor element is 30% to 50% of an area of the first electrode.

12. The semiconductor element package of claim 1, comprising a light transmission substrate arranged on the body,
wherein the light transmission substrate transmits light in an ultraviolet wavelength band.

13. The semiconductor element package of claim 1, wherein the semiconductor element generates light in an ultraviolet wavelength band.

14. A light-emitting device comprising:
a circuit board; and
a plurality of semiconductor element packages arranged on the circuit board,
wherein the semiconductor element package includes a body including a cavity, a first electrode and a second electrode arranged on a bottom surface of the cavity, a semiconductor element arranged on the first electrode, a protective element arranged on the first electrode to be spaced apart from the semiconductor element, a first wire configured to electrically connect the semiconductor element to the second electrode, and a second wire configured to electrically connect the protective element to the second electrode,
wherein the second electrode is arranged to be spaced apart from the first electrode in a first direction,
the second electrode overlaps the semiconductor element in the first direction,
the protective element is arranged to deviate from the semiconductor element in a second direction perpendicular to the first direction, and
the first electrode includes a groove arranged between the semiconductor element and the protective element.

15. The light-emitting device of claim 14, wherein the first electrode includes a first sub region overlapping the second electrode in the first direction and a second sub region overlapping the second electrode in the second direction.

16. The light-emitting device of claim 15, wherein:
the semiconductor element is arranged in the first sub region; and
the protection device is arranged in the second sub region.

17. The light-emitting device of claim 15, wherein the protection device overlaps the second electrode in the second direction.

18. The light-emitting device of claim 15, comprising a first separation region arranged between the second electrode and the first sub region, and a second separation region arranged between the second electrode and the second sub region,
wherein the groove is connected to the first separation region and the second separation region.

19. The light-emitting device of claim 14, wherein:
the groove includes a first groove facing a first corner of the semiconductor element and a second groove facing a third corner of the semiconductor element; and
the first corner and the third corner face each other in a diagonal direction.

20. The light-emitting device of claim 14, wherein:
the semiconductor element includes a conductive substrate, a semiconductor structure arranged on the conductive substrate, and an electrode pad electrically connected to a second conductive semiconductor layer of the semiconductor structure; and
the conductive substrate is electrically connected to a first conductive semiconductor layer of the semiconductor structure.

21. The light-emitting device of claim 20, comprising an alloy layer arranged between the conductive substrate and the first electrode.

22. The light-emitting device of claim 14, wherein:
the first wire includes an end arranged at the second electrode;
the second wire includes an end arranged at the second electrode; and
the end of the second wire is arranged farther from the semiconductor element than the end of the first wire.

23. The light-emitting device of claim 14, wherein an area of the semiconductor element is 30% to 50% of an area of the first electrode.
